(19) United States
(12) Patent Application Publication
(10) Pub. No.: US 2024/0332104 A1
(43) Pub. Date: Oct. 3, 2024

(54) Component Carrier With Reinforcement Layer Structure and Manufacturing Method Using Two Temporary Carriers

(71) Applicant: AT&S Austria Technologie & Systemtechnik AG, LEOBEN (AT)

(72) Inventor: Minwoo Lee, Chongqing (CN)

(21) Appl. No.: 18/191,867

(22) Filed: Mar. 28, 2023

(51) Int. Cl. H01L 23/31; H01L 21/56; H01L 23/00

(52) U.S. Cl. CPC H01L 23/3121; H01L 21/561; H01L 21/568; H01L 24/19; H01L 24/20; H01L 24/95; H01L 2224/19; H01L 2224/2101; H01L 2224/95001

(57) ABSTRACT

A component carrier includes a stack having at least one electrically insulating layer structure and at least one electrically conductive layer structure; a component, at least partially embedded in the electrically insulating layer structure, wherein component connection pads provided at a first main surface of the component are flush with a first main surface of the electrically insulating layer structure; and a reinforcement layer structure, provided over a second main surface of the electrically insulating layer structure, opposed to the first main surface of the electrically insulating layer structure. A method for manufacturing a component carrier is also disclosed.

### TECHNICAL FIELD

Embodiments disclosed herein relate to a component carrier and methods for manufacturing a component carrier, respectively.

### BACKGROUND ART

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable so as to be operable even under harsh conditions.

In particular, embedding a component (e.g., a passive or active electronic component) into a component carrier layer stack may be considered a challenge, especially regarding the constant trend towards miniaturization (e.g., reduction in thickness (z) direction). Meanwhile warpage is a very big technical barrier for the manufacturing and product quality, especially for panel level packaging. Since the embedded component requires a certain tolerance in the component carrier thickness direction, fine line structures with respect to electric connections to the component (in particular a redistribution structure) may be challenging to form. Further, a thin layer stack (or a thick layer stack) may be prone to warpage during embedding and manufacturing processes. Additionally, thermal deformation may be a further source of potential defects during the manufacture process.

### SUMMARY

There may be a need to embed a component in a component carrier in an efficient and reliable manner. A component carrier and a manufacture method are provided.

According to a first aspect of the disclosure, there is described a component carrier. The component carrier including i) a stack having at least one electrically insulating layer structure and/or at least one electrically conductive layer structure, ii) a (electronic) component (active or passive), at least partially embedded in the electrically insulating layer structure (in particular a (through hole of a) core layer structure), wherein component connection pads (electric contacts/terminals) provided at a first main surface of the component are (essentially) flush with a first main surface of the electrically insulating layer structure (this feature may reflect the use of a first temporary carrier, in particular a first temporary carrier with a very flat surface, at the first main surface, see below); and iii) a reinforcement layer structure, provided over a second main surface of the electrically insulating layer structure ((in particular coupled to the second main surface), opposed to the first main surface of the electrically insulating layer structure (this feature may reflect the use of a second temporary carrier at the second main surface, e.g. when the reinforcement layer structure is at least partially provided together with the secondary temporary carrier, see below).

According to a second aspect of the disclosure, there is described a method of manufacturing a component carrier (e.g., as described above). The method includes i) providing a first temporary carrier (in particular a glass substrate), ii) forming a component carrier preform with at least one electrically insulating layer structure and/or at least one electrically conductive layer structure on the first temporary carrier, iii) embedding at least one component at least partially in (a cavity in) the electrically insulating layer structure formed on the first temporary carrier, so that component connection pads provided at a first main surface of the component abut (in particular in direct physical contact) against the first temporary carrier (so that the component connection pads at the first main surface of the component are flush with the main surface of the electrically insulating layer structure, see above), iv) providing (in particular forming) a reinforcement layer structure at the second main surface of the component carrier preform (in particular so that the reinforcement layer structure is coupled to the second main surface, being opposed to the first main surface, of the embedded component) (in particular before providing a second temporary carrier), v) providing a second temporary carrier (in particular a dielectric layer structure) and coupling/attaching the component carrier preform on the second temporary carrier at a second main surface of the component carrier preform, opposed to the first main surface of the component carrier preform, vi) removing the first temporary carrier from a first main surface of the component carrier preform (in particular attaching the second temporary carrier before removing the first temporary carrier), and vii) removing the second temporary carrier.

Hereby, the first temporary carrier is different (e.g., regarding material, physical property, thickness, surface properties, etc.) from the second temporary carrier.

### Overview of Embodiments

In an exemplary embodiment, the first temporary carrier may provide a suitable flatness and stiffness, for example glass, steel, ceramic, and advanced composite material, and it may be detachable on one side. The second temporary carrier may be a kind of FR4 core such as DCF (detachable copper foil) laminate. It may comprise detachable layer(s) on both sides, it may be a carrier of layers.

In the context of the present document, the term “electrically insulating layer structure” may particularly denote a dielectric layer structure that is suitable for at least partially embedding a component. In a preferred example, the electrically insulating layer structure is configured as a core layer structure of the stack/component carrier. In an example, the electrically insulating layer structure is provided as part of a copper clad laminate (CCL). The dielectric material may be reinforced e.g., by glass, carbon, or aramid fibers/spheres. Thereby, the layer structure may become stress designable (compared to normal material which has anisotropic stress extension in XYZ direction). Thus, the XYZ direction of the electrically insulating layer structure may have different properties and have a high modulus and low coefficient of thermal expansion (CTE), so that a flat main surface (of the component) may be provided with the application of inorganic carrier (such as glass). Meanwhile, good alignment of the component on the flat carrier may be provided.

In the context of the present document, the term “reinforcement (layer) structure” may particularly denote any (layer) structure (such as, e.g., prepreg, metal, or a layer combined with resin and metal with electrically insulating and/or conductive function or without electrically insulating and/or conductive function) suitable to provide a reinforcement functionality to the component carrier (stack). In particular, in case of a thin component (carrier), warpage and/or thermal deformation may be considered a challenge. Hence, a reinforcement layer structure, formed during the manufacture process, may protect the component carrier efficiently during further manufacture steps and as a finished product. Different examples for the reinforcement layer structure are described in the following. The reinforcement (layer) structure may comprise a single dielectric/metal layer. In another example, the reinforcement layer structure comprises two or more layers, for example an electrically conductive layer sandwiched between two dielectric layers or the other way around or one dielectric layer attaching with one metal layer.

In the context of the present document, the term “component carrier” may particularly denote any support structure which is capable of accommodating one or more components thereon and/or therein for providing mechanical support and/or electrical connectivity and/or thermal connectivity. In other words, a component carrier may be configured as a mechanical and/or electronic and/or thermal carrier for components. In particular, a component carrier may be one of a printed circuit board, an organic interposer, a metal core substrate, an inorganic substrate, inorganic interposer, an IC (integrated circuit) substrate, a mounting base.

The term “component carrier preform” (or semi-finished product) may refer to a component carrier under manufacture, i.e., a component carrier that has not yet been completely finished. In a specific example, a component carrier preform may comprise openings to be filled with electrically conductive material (to thereby form vias), wherein surfaces (such as a pad, plating through hole, etc.) are exposed at the bottom of the openings. In a corresponding component carrier, in this example, the openings may be filled with the electrically conductive material to form the electrical connection portion which may then be connected to the baseline etch surfaces.

In the context of the present document, the term “IC substrate” may particularly denote a small component carrier. An IC substrate may be a, in relation to a PCB, comparably small component carrier onto which one or more components may be mounted and that may act as a connection medium between one or more chip(s) and a further PCB. More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. In an example, an IC substrate may be seen as an interposer, for example between electronic components and a printed circuit board.

In the present context, an IC substrate should not be understood as any substrate suitable to bear an IC. Instead, the term “IC substrate” may be a technically established term for a specific, high density PCB that comprises common PCB materials.

According to an exemplary embodiment, the disclosure may be based on the idea that a component can be embedded in a component carrier in an efficient and reliable manner, when i) component connection pads are formed flush with the embedding material (insulating layer structure), and ii) a reinforcement layer structure is provided to the stack during the manufacture process. In this manner, both opposed main surfaces of the component carrier stack may be individually optimized, yielding a high quality component carrier, in particular with a low thickness and fine line structures. Additionally, a lower warpage and rigid structure may be provided with thin assembly package structure.

Even though it is known to use a temporary carrier during the manufacture of a component carrier, it has been surprisingly found by the inventors that an especially efficient manufacture can be enabled by using different temporary carriers with different properties.

The component connection pads are formed flush with the insulating layer structure (see i) by means of a first temporary carrier, preferably a glass substrate, that comprises an especially flat surface to enable the flush architecture that can be seen in the component carrier product. Thereby a fine-line structure build-up, e.g. a redistribution layer structure, may be enabled. In particular, a RDL structure may further stabilize the component carrier against warpage/thermal deformation.

The reinforcement layer structure (see ii) may be provided together (or in advance) with a second temporary carrier, which is preferably designed to enable component carrier manufacture on both opposed main surfaces. Since thin component (carriers) may be prone to warpage issues, it may be desirable to use thicker structures (e.g., a temporary carrier with component carrier preforms at both surfaces, see e.g., FIG. 5) during the manufacture. Additionally, the reinforcement layer structure may efficiently stabilize the component carrier (preform) during manufacture and as a final product.

According to an embodiment, the reinforcement layer structure comprises a reinforcement dielectric layer structure. This may provide the advantage that a dielectric stiffener may be directly provided during the manufacture process in a cost-efficient manner. A corresponding example is shown in FIG. 1. In an example, a (thin) metal/copper layer is arranged between the reinforcement dielectric layer structure and the electrically insulating layer structure (core layer structure). In an example, the embedded component is in direct contact with the reinforcement dielectric layer structure or the metal/copper layer in between. In another example, the embedded component is not in direct contact with the reinforcement dielectric layer structure or the metal/copper layer in between.

According to a further embodiment, the reinforcement dielectric layer structure comprises at least one of: a fully cured resin, a fiber-reinforced resin, (e.g., a prepreg), a fiber-free reinforced (e.g., by spheres) resin (e.g., ABF), a fiber-free resin. This may provide the advantage that established and economically important PCB-materials can be directly applied.

According to a further embodiment, the reinforcement layer structure comprises a first reinforcement electrically conductive layer structure. This may provide the advantage that a metal stiffener may be directly applied which may further provide thermal (and/or electrically conductive) functionality.

According to a further embodiment, the first reinforcement electrically conductive layer structure is sandwiched between two reinforcement dielectric layer structures. This may provide the advantage that the metal stiffener is well protected and thermal deformation may be balanced by the dielectric layer structures. A corresponding example is shown in FIG. 2. The reinforcement dielectric layer structures may correspond to those described above or may be different.

According to a further embodiment, the reinforcement layer structure comprises a second reinforcement electrically conductive layer structure, in particular wherein the reinforcement dielectric layer structure is sandwiched between a first reinforcement electrically conductive layer structure and a second reinforcement electrically conductive layer structure. Depending on the desired application and the further materials of the component carrier, different architectures may be preferable. A corresponding example is shown in FIG. 3.

According to a further embodiment, at least one reinforcement electrically conductive layer structure is patterned or not patterned. By patterning one or more reinforcement electrically conductive layer structure(s), the reinforcement layer structure may further enable specific electric connections within the component carrier. For example, the reinforcement electrically conductive layer structure may be electrically connected to an electrically conductive layer structure and/or a via, thereby establishing a high flexibility of connection architectures. It is also possible to form the redistribution layer structure under the component by taking use of the reinforcement electrically conductive structure. A corresponding example is shown in FIG. 4.

According to a further embodiment, the patterned conductive layer structure comprises and/or is connected to a thermal dissipation structure, in particular at least one thermal via. Thereby, an especially efficient thermal management within the component carrier may be enabled.

According to a further embodiment, the component comprises a thickness of 100 μm or smaller, in particular 80 μm or smaller. This may provide the advantage that a thin component can be efficiently embedded, and the whole component may be thinner in this respect. Nevertheless, such a small thickness may only be enabled by the reinforcement layer structure and/or the redistribution layer structure as a stabilization.

According to a further embodiment, the electrically insulating layer structure (configured as a core layer structure, more in particular a copper clad laminate) comprises a thickness of 30 μm to 50 μm thicker than the component. Thereby, a very thin component carrier may be enabled which is still stable against warpage. In an example, the component carrier comprises a thickness of 150 μm or smaller, in particular 130 μm or smaller, more in particular 110 μm or smaller.

In an example, the thickness of component and core layer structure is essentially similar, or the chip thickness is slightly lower, thereby providing efficient encapsulation and die attachment performance.

According to a further embodiment, the component carrier further comprising at least one further electrically insulating layer structure provided on the first main surface the electrically insulating layer structure. In this manner, an efficient build-up process of a multi-layer stack may be performed. In an example, the reflection of the second temporary carrier is also imparted through the provision of an additional dielectric layer on the first main surface together with or instead of the redistribution layer structure.

According to a further embodiment, the component carrier further comprises: a redistribution layer structure, provided on the electrically insulating layer structure (in particular coupled to the first main surface of the embedded component). The RDL structure may enable an efficient and reliable electric connection to the (connection pads of the) embedded component, in particular since the connection pads are flush with the main surface. The RDL structure may be formed as a build-up process while the component carrier preform is still attached to the second temporary carrier. Together with the opposed reinforcement layer structure, the RDL structure may contribute to the provision of a thin, but (warpage) robust component carrier.

According to a further embodiment, the first temporary carrier comprises a glass substrate. This may provide the advantage that an especially flat (and smooth) and stable surface is provided, so that the connections pads can be adjusted to the desired position, in particular flush with the first insulating layer structure main surface.

In this context, the term “glass” may in particular refer to a non-crystalline and amorphous solid. In a preferred example, the glass comprises silicate, in particular silicon dioxide (SiO₂). In a further example, the glass comprises at least one silane and/or siloxane compound. In yet another example, the glass may comprise functional groups, e.g., hydrophilic and/or hydrophobic functional groups, in particular at the main surfaces. Since the glass barrier layer is a (continuous or discontinuous) layer, it comprises two main surfaces opposite to each other.

In an example, the main surface of the insulating layer structure (core) comprises a thickness variation like roughness or recess (happened on the surface). Hereby, the glass carrier could provide very flat surface and when the core layer structure with the embedded component is attached on the glass, the undulation of the main surface may be removed/balanced. Thereby, fine-line structuring may be improved as well. Preferably, by providing the glass substrate, the first main surface of the electrically insulating layer structure may be provided with a flat/smooth surface as well.

In an example, the first temporary carrier comprises a thickness of 500 μm or more. By providing an especially thick temporary carrier, the (very thin) component carrier preform may be efficiently stabilized.

According to a further embodiment, the second temporary carrier comprises at least one of a dielectric layer structure (in particular a core layer structure), an electrically conductive layer structure, a release layer structure. This may provide the advantage that the second temporary carrier is configured as a robust and stable structure that can efficiently prevent warpage, especially when both opposed main surfaces are applied to attach a respective component carrier preform.

According to a further embodiment, the first temporary carrier and/or the second temporary carrier is coreless. This may enable a higher design-flexibility and lower thickness, even though the component carrier preform(s) may still be sufficiently protected against warpage. In an example, the symmetric structure is likely to control the warpage during manufacturing.

According to a further embodiment, the second temporary carrier comprises two opposed main surfaces, wherein the component carrier preform is attached to the first main surface of the second temporary carrier, and wherein a further component carrier perform (in particular being comparable, more in particular being similar to the component carrier preform, is attached to the second main surface of the second temporary carrier.

In this manner, two component carriers are manufactured at the same time (simultaneously, symmetrically) at the opposed main surfaces of the temporary carrier. On the one hand, this measure may speed up the production process. On the other hand, architecture of two component carriers with a temporary carrier in between yields a thick and robust structure during manufacturing, even though the component carrier preforms as such would be considered thin structures.

According to a further embodiment, forming further (layer) structures and/or providing at least one further component on/to the component carrier and on the further component carrier (both attached to the second temporary carrier) is done symmetrically or asymmetrically. In other words, a symmetrical build-up on both opposed main surfaces of the temporary carrier may be enabled, thereby eventually improving the robustness and reducing the warpage issue.

According to a further embodiment, the reinforcement layer structure is formed on the at least one electrically insulating layer structure and/or embedded component (depending on the component thickness and the core thickness). Thereby, small space requirements may be combined with a robust protection of the embedded component.

According to a further embodiment, the reinforcement layer structure is at least partially provided together with the second temporary carrier, in particular sandwiched between the second temporary carrier and the component carrier preform. Thus, attaching the reinforcement layer structure and the secondary temporary carrier may be provided within the same step, thereby increasing production speed/efficiency and making the semi-finished products more stable.

According to a further embodiment, the method further comprises: forming at least one further electrically insulating layer structure provided on the first main surface of the electrically insulating layer structure (see above).

According to a further embodiment, the method further comprises: forming a redistribution layer structure on the electrically insulating layer structure and/or forming the electrically insulating layer as part of a redistribution layer structure (in particular coupling the redistribution layer structure to the connection pad surface of the embedded component). The RDL structure may be formed, while the component carrier preform is still attached at the second temporary carrier. Accordingly, a stable and reliable build-up may be enabled. Further, due to the flat core layer surface and/or the flush connection pads of the component, fine-line structures may be efficiently produced and fine line structuring may be realized and the component can be interconnected with the component carrier efficiently since it has symmetrical structure which provides lower panel warpage. Therefore, flat patterning level can be expected for fine line structuring.

According to a further embodiment, forming the redistribution layer structure comprises: a semi-additive process, a modified SAP or semiconductor process. Accordingly, established and economically important PCB-manufacturing methods may be directly applied.

According to a further embodiment, embedding comprises: i) forming a cavity in the at least one electrically insulating layer structure, ii) placing the component into the cavity, and iii) encapsulating the component with an encapsulation material. Accordingly, an established PCB-manufacturing or IC substrate manufacturing methods may be directly applied.

According to a further embodiment, the method further comprises: (at least partially) exposing the second main surface of the component, in particular by grinding and/or etching. Thereby, the second main surface may be formed especially flat/smooth, so that the reinforcement layer structure can be attached in an efficient and robust manner.

According to a further embodiment, the redistribution layer structure reflects the manufacture step of using the second temporary carrier, because due to the first temporary carrier, the component pads flush with the first main surface (both abutting against said first temporary carrier and the reinforcement layer structure is provided on the second main surface opposed to the first temporary carrier), whereas the redistribution layer structure is built on the first main surface after the first temporary carrier removal, then opposed to the second surface where the second temporary carrier is provided. The redistribution layer structure could also be provided on the second surface without the presence of the second temporary carrier, but due to the thin component carrier, this would potentially cause warpage of the component carrier.

According to a further embodiment, the reinforcement dielectric layer structure can balance the whole package to reduce the warpage even in case of an asymmetric structure (it could compensate e.g., with the RDL side). The reinforcement layer structure may also be a thermal dissipation layer. The reinforcement structure may be a mixture of dielectric material and metal. The property of different structure depends on the property of RDL (it may be flexibly reorganized with different material based on the material own property). The reinforcement layer structure comprising different materials (e.g., different dielectric material with different Young's modulus and metal) may control the dimension change of the package (dielectric material might be possible to go back to original status although it is likely to change), while the metal, like copper, is not likely to go back to original. Therefore, the different material combined would balance the property.

According to a further embodiment, the following advantages may be provided by the described concept: stable panel level packaging with fine line RDL, higher thermal and mechanical stability, lower packaging costs, recycling of glass substrate.

In an embodiment, the component carrier is configured as one of a printed circuit board, a substrate (in particular an IC substrate), and an interposer.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In the context of the present application, the term “stack” may particularly denote a sequence of two or more layer structures formed on top of each other. For instance, layer structures of a layer stack may be connected by lamination, i.e., the application of heat and/or pressure. Preferably, the stacked layer structures may be arranged parallel to each other. It may function with the insulating and electrical conductivity in the component carrier.

In the context of the present application, the term “layer structure” may particularly denote a continuous layer, a patterned layer, or a plurality of non-consecutive islands within a common plane. It may comprise the electrical insulating portion and/or electrical transmission portion.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure (dielectric layer) comprises at least one of the group consisting of a resin or a polymer, such as epoxy resin, cyanate ester resin, benzocyclobutene resin, bismaleimide-triazine resin, polyphenylene derivate (e.g., based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g., fibers impregnated with the above-mentioned resins is called prepreg. These prepregs are often named after their properties e.g., FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure (for example electric interconnection, terminal, pad, via, etc.) comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack.

The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mk (milliKelvin). Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, also other components, in particular those which generate and emit electromagnetic radiation and/or are sensitive with regard to electromagnetic radiation propagating from an environment, may be used as component(s).

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1, FIG. 2, FIG. 3, and FIG. 4 respectively show a component carrier with a reinforcement layer structure according to an exemplary embodiment of the disclosure.

FIG. 5 shows a component carrier preform according to an exemplary embodiment of the disclosure.

FIG. 6A, FIG. 6B, FIG. 6C, FIG. 6D, FIG. 6E, FIG. 6F, FIG. 6G, FIG. 6H, FIG. 6I, FIG. 6J, FIG. 6K, and FIG. 6L show a method of manufacturing a component carrier according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

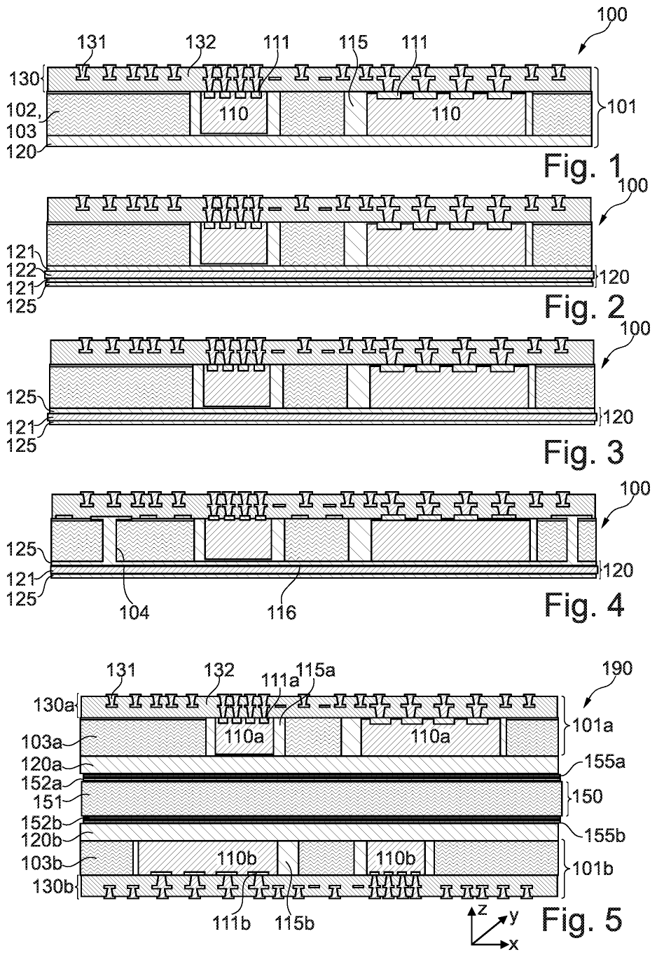

FIG. 1 shows a component carrier 100 carrier according to an exemplary embodiment of the disclosure. The component carrier 100 comprises a layer stack 101 with an electrically insulating layer structure 102 configured as a core layer structure 103 (e.g., a fully cured core material) and an electrically conductive layer structure (not shown here). In this example, the electrically insulating layer structure 102 comprises a resin that is glass, carbon, or aramid reinforced. An electronic component 110 is embedded (encapsulated in an encapsulation/mold material 115), in the electrically insulating layer structure 102, i.e., in the core 103. In a specific example, the thin component 110 comprises a thickness of 100 μm (in particular 80 μm) or smaller (or thicker). In an example, dielectric layer 103 can be designed by chip thickness. Further, the electrically insulating layer structure (in particular configured as a core layer structure) comprises a thickness of 5 μm to 50 μm thicker than the component (thin component carrier preform). It follows that the component carrier 100 is designed with a very low thickness in this example.

Connection pads 111 are provided at a first main (upper) surface of the component 110 and are flush with a first main (upper) surface of the electrically insulating layer structure 102. As described below, this structural feature reflects the use of a first temporary carrier at the first main surface.

On top of the electrically insulating layer structure 102, there is arranged a redistribution layer structure 130 which is coupled to the first main surface of the embedded component 110. The redistribution layer (RDL) structure 130 comprises a plurality of electrically conductive RDL vias/traces 131 in and/or on an electrically insulating RDL material 132. RDL vias 131 arranged (in vertical direction z) above the component 110 are directly electrically connected to the connection pads 111 of the component 110. Since the connection pads 111 are flush with the main surface of the electrically insulating layer structure 102, an especially efficient connection can be enabled.

The component carrier 100 further comprises a reinforcement layer structure, provided over a second main (lower) surface of the electrically insulating layer structure 102, opposed to the first main (upper) surface of the electrically insulating layer structure 102. This structural feature can reflect the use of a second temporary carrier (see below) at the second main surface, which can provide the reinforcement layer structure 120. In the example of FIG. 1, the reinforcement layer structure 120 is a reinforcement dielectric layer structure 121 which comprises for example a fiber-free reinforced resin such as ABF. In another example, the reinforcement dielectric layer structure 121 comprises a prepreg or mold film.

FIG. 2 shows a component carrier 100 carrier according to a further exemplary embodiment of the disclosure. The component carrier 100 of FIG. 2 is comparable with the one described for FIG. 1, yet with the difference that the reinforcement layer structure 130 comprises a first reinforcement electrically conductive layer structure 122 (e.g., a copper layer, metal stiffener) sandwiched between two reinforcement dielectric layer structures 121 (e.g., as described for FIG. 1 above). The outermost layer of the stack at the second main (lower) surface is in this example a second reinforcement electrically conductive layer structure 125 (e.g., a metal layer being thinner than metal layer 122).

FIG. 3 shows a component carrier 100 carrier according to a further exemplary embodiment of the disclosure. The component carrier 100 of FIG. 3 is comparable with those described for FIGS. 1 and 2, yet with the difference that the reinforcement layer structure 130 comprises the reinforcement dielectric layer structure 121 sandwiched between the first and the second reinforcement electrically conductive layer structure 125, wherein the first and the second reinforcement electrically conductive layer structures 125 have essentially the same thickness.

FIG. 4 shows a component carrier 100 carrier according to a further exemplary embodiment of the disclosure. The component carrier 100 of FIG. 4 is comparable with the one described for FIG. 3, yet with the difference that the first and the second reinforcement electrically conductive layer structures 125 are patterned so that openings 116 remain, which are filled with dielectric material. Hereby, the embedded patterned conductive layer structure 125 is connected to an electrically conductive via 104 that extends through the core layer structure 103. It can function as thermal dissipation structure or even form the redistribution layer structure under the component by using the reinforcement conductive structure.

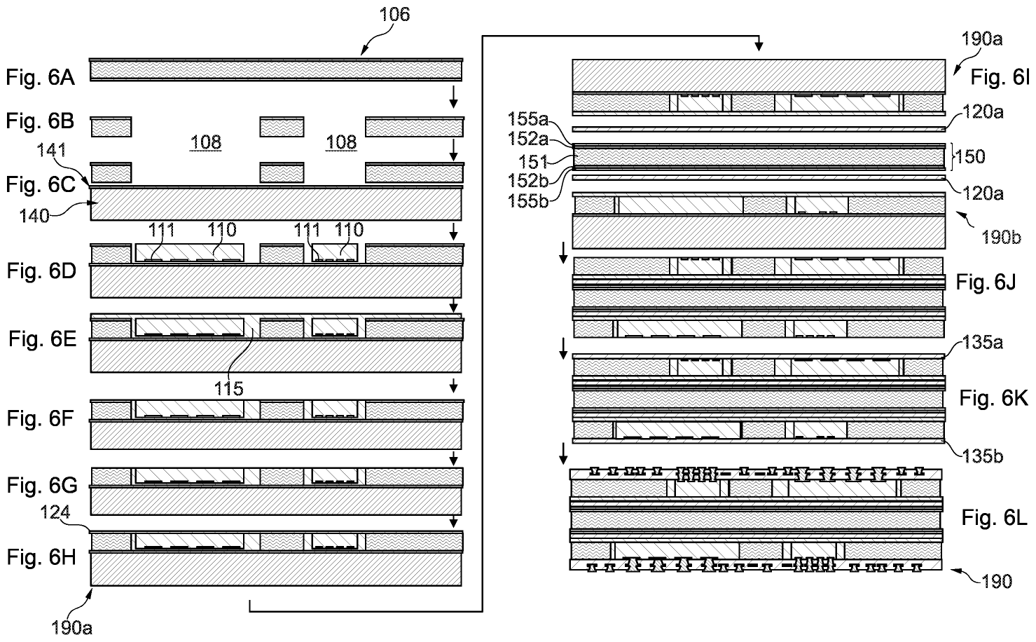

FIG. 5 shows a component carrier preform (semi-finished product) 190 according to an exemplary embodiment of the disclosure. Said component carrier preform 190 can be formed according to the method described for FIGS. 6A to 6L below. There is provided a second temporary carrier 150 that comprises two opposed main surfaces 152a, 152b. Exposed at said main surfaces 152a, 152b are second release layers 155a, 155b on metal/copper layers. Sandwiched between the metal layers is a dielectric core layer structure 151.

A first component carrier preform 190a is attached to the first main surface 152a of the second temporary carrier 150, and a second component carrier perform 190b, being comparable to the first component carrier preform 190a, is attached to the second main surface 152b of the second temporary carrier 150. Each of the component carrier preforms 190a, 190b is comparable to the component carrier 100 described for FIG. 1 above. The redistribution layer structures 130a, 130b have been formed after removing a first temporary carrier.

Due to the thickness of the semi-finished product 190, the (actually thin) component carrier preforms and the embedded component 110 are well protected against warpage.

FIG. 6A, FIG. 6B, FIG. 6C, FIG. 6D, FIG. 6E, FIG. 6F, FIG. 6G, FIG. 6H, FIG. 6I, FIG. 6J, FIG. 6K, and FIG. 6L show a method of manufacturing a component carrier 100 according to an exemplary embodiment of the disclosure.

In FIG. 6A an electrically insulating layer structure 102 is provided as a core layer structure 103. In a specific example, said layer comprises a CCL (copper clad laminate 106) core layer.

In FIG. 6B a cavity 108 is formed in the electrically insulating layer structure 102, e.g., by drilling through the CCL and electrically insulating layer structure.

In FIG. 6C a first temporary carrier 140, here a glass substrate, is provided below the electrically insulating layer structure 102. A first (double) release layer 141 is arranged between first temporary carrier 140 and electrically insulating layer structure 102. The first temporary carrier 140 is comparably thick, comprising a thickness of more than 500 μm.

In FIG. 6D a component 110 is placed into the cavity 108 and onto the first temporary carrier 140, so that connection pads 111 at a first surface of the component 110 are in contact with the first release layer 141 and flush with the first main surface of the electrically insulating layer structure 102.

In FIG. 6E the component 110 in the cavity 108 is encapsulated with an encapsulation material 115 (e.g., a mold film, ABF, etc.) that also covers the second main surface of the electrically insulating layer structure 102.

In FIG. 6F the encapsulation material 115 is removed from the second main surface to expose the electrically insulating layer structure 102, e.g., by grinding and/or (plasma) etching.

In FIG. 6G further, the copper layer of the copper clad laminate is also removed by etching (like flash etching).

In FIG. 6H a first reinforcement electrically conductive layer structure 124 is provided on the exposed second main surface of the electrically insulating layer structure 102, e.g., by lamination. Thereby, a component carrier preform 190a is obtained.

In FIG. 6I a second temporary carrier 150 is provided that comprises two opposed main surfaces 152a, 152b. Exposed at said main surfaces 152a, 152b are second release layers 155a, 155b on metal/copper layers. Sandwiched between the metal layers is a dielectric core layer structure 151. The component carrier preform 190a is attached to the upper main surface 152a, while a comparable component carrier preform 190b is attached to the opposed lower main surface 152b. In between the second release layers 155a, 155b and the component carrier preforms 190a, 190b, respective reinforcement dielectric layer structures 120a, 120b (e.g., prepreg, ABF, bond film, etc.) are provided. Said reinforcement dielectric layer structure 120a, 120b can be provided together with the secondary temporary carrier 150, or separately in advance.

In FIG. 6J the respective first temporary carriers 140 are removed.

In FIG. 6K on the exposed first main surfaces of the electrically insulating layer structures 102, respective RDL preforms 135a, 135b are arranged.

In FIG. 6L the RDL structures 130a, 130b are completely build-up (symmetrically) to yield the component carrier preform 190 shown in FIG. 5. Once the second temporary carrier 150 is detached, finished component carrier products 100 with reinforcement layer structures 130 are obtained, as shown e.g., in FIG. 1.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

### REFERENCE SIGNS

100 Component carrier
101 Stack
102 Electrically insulating layer structure
103 Core layer structure
104 Electrically conductive layer structure, via
106 Copper-clad laminate
108 Cavity
110 Component
111 Component connection pad
115 Encapsulation material
120 Reinforcement layer structure
121 Reinforcement dielectric layer structure
122 Metal layer structure
124 First reinforcement electrically conductive layer structure
125 Second reinforcement electrically conductive layer structure
130 Redistribution layer structure
131 Electrically conductive RDL via/trace
132 Electrically insulating RDL material
135 RDL preform
140 First temporary carrier
141 First release layer
150 Second temporary carrier
151 Dielectric core layer structure of second temporary carrier
152 Electrically conductive layer structure of second temporary carrier
155 Second release layer
190 Component carrier preform, semi-finished component carrier
a for first component carrier preform features
b for second component carrier preform features

1. A component carrier, comprising:
a stack having at least one electrically insulating layer structure and at least one electrically conductive layer structure;
a component, at least partially embedded in the electrically insulating layer structure,
wherein component connection pads provided at a first main surface of the component are flush with a first main surface of the electrically insulating layer structure; and
a reinforcement layer structure, provided over a second main surface of the electrically insulating layer structure, opposed to the first main surface of the electrically insulating layer structure.

2. The component carrier according to claim 1,
wherein the reinforcement layer structure comprises a reinforcement dielectric layer structure.

3. The component carrier according to claim 2,
wherein the reinforcement dielectric layer structure comprises at least one of: a fully cured resin, a fiber-reinforced resin, in particular a prepreg, a fiber-free reinforced resin, in particular ABF, a fiber-free resin.

4. The component carrier according to claim 1,
wherein the reinforcement layer structure comprises a first reinforcement electrically conductive layer structure, in particular wherein the first reinforcement electrically conductive layer structure is sandwiched between two reinforcement dielectric layer structures.

5. The component carrier according to claim 1,
wherein the reinforcement layer structure comprises a second reinforcement electrically conductive layer structure, in particular wherein the reinforcement dielectric layer structure is sandwiched between the first and the second reinforcement electrically conductive layer structure.

6. The component carrier according to claim 5,
wherein at least one reinforcement electrically conductive layer structure is patterned, in particular wherein the patterned conductive layer structure comprises a thermal dissipation structure, in particular at least one thermal via.

7. The component carrier according to claim 1,
wherein the component comprises a thickness of 100 μm or smaller, in particular 80 μm or smaller.

8. The component carrier according to claim 1,
wherein the electrically insulating layer structure, in particular configured as a core layer structure, comprises a thickness of 30 μm to 50 μm thicker than the component.

9. The component carrier according to claim 1, further comprising:
at least one further electrically insulating layer structure provided on the first main surface of the electrically insulating layer structure.

10. The component carrier according to claim 1, further comprising:
a redistribution layer structure, provided on the electrically insulating layer structure, in particular coupled to the first main surface of the embedded component.

11. A method of manufacturing a component carrier, the method comprising:
providing a first temporary carrier;
forming a component carrier preform with at least one electrically insulating layer structure and at least one electrically conductive layer structure on the first temporary carrier;
embedding at least one component at least partially in the electrically insulating layer structure formed on the first temporary carrier, so that component connection pads provided at a first main surface of the component abut against the first temporary carrier;
providing a reinforcement layer structure at the second main surface of the component carrier preform;
providing a second temporary carrier and attaching the component carrier preform on the second temporary carrier at a second main surface of the component carrier preform, opposed to the first main surface of the component carrier preform;
removing the first temporary carrier from a first main surface of the component carrier preform; and
removing the second temporary carrier;
wherein the first temporary carrier is different from the second temporary carrier.

12. The method according to claim 11,
wherein the first temporary carrier comprises a glass substrate, in particular with a thickness of 500 μm or more.

13. The method according to claim 11,
wherein the second temporary carrier comprises at least one of a dielectric layer structure, in particular a core layer structure, an electrically conductive layer structure, a release layer structure.

14. The method according to claim 11,
wherein the first temporary carrier and/or the second temporary carrier is coreless.

15. The method according to claim 11,
wherein the second temporary carrier comprises two opposed main surfaces,
wherein the component carrier preform is attached to the first main surface of the second temporary carrier, and
wherein a further component carrier perform, in particular being comparable to the component carrier preform, is attached to the second main surface of the second temporary carrier, in particular wherein forming the further structures and/or providing at least one further component on the component carrier and on the further component carrier attached to the second temporary carrier is done symmetrically.

16. The method according to claim 11,
wherein the reinforcement layer structure is formed on the at least one electrically insulating layer structure and in particular on the embedded component, in particular wherein the reinforcement layer structure is at least partially provided together with the second temporary carrier.

17. The method according to claim 11, further comprising:
forming at least one further electrically insulating layer structure provided on the first main surface the electrically insulating layer structure.

18. The method according to claim 11, further comprising:
forming a redistribution layer structure on the electrically insulating layer structure, in particular coupling the redistribution layer structure to the connection pad surface of the embedded component, in particular wherein forming the redistribution layer structure comprises: a semi-additive process, in particular a modified SAP.

19. The method according to claim 11, wherein embedding comprises:
forming a cavity in the at least one electrically insulating layer structure;
placing the component into the cavity; and
encapsulating the component with an encapsulation material.

20. The method according to claim 11, further comprising:
at least partially exposing the second main surface of the component, in particular by grinding and/or etching.
